(19) United States
(12) Patent Application Publication
(10) Pub. No.: US 2001/0001495 A1
(43) Pub. Date: May 24, 2001

(54) METHOD FOR REDUCING CONTACT RESISTANCE

(76) Inventors: DAHCHENG LIN, HSINCHU (TW); WAN-YIH LIEN, HSINCHU (TW); MENG-JAW CHERNG, SHUANG-SHE (TW)

Correspondence Address: J C PATENT INC, 1340 REYNOLDS AVE, SUITE114, IRVINE, CA, 92614

(21) Appl. No.: 09/328,978

(22) Filed: Jun. 9, 1999

(30) Foreign Application Priority Data
Apr. 6, 1999 (TW) 88105421

(51) Int. Cl. H01L 21/3205; H01L 21/4763; H01L 29/76; H01L 31/113; H01L 29/94; H01L 31/062; H01L 31/119

(52) U.S. Cl. 257/341

(57) ABSTRACT

A method for reducing a contact resistance is described. The method is suitable for a wafer that comprises a WSiₓ layer, a native oxide on the WSiₓ layer, and a dielectric layer surrounding and partially covering the WSiₓ layer, wherein the dielectric layer has a contact hole exposing the native oxide. The wafer is placed into a vacuum system. A first polysilicon layer is deposited on the native oxide. The first polysilicon layer and the native oxide are annealed. A second polysilicon layer is formed on the WSiₓ. The wafer is removed from a vacuum system.

### CROSS-REFERENCE TO RELATED APPLICATION

This application claims the priority benefit of Taiwan application serial no. 88105421, filed Apr. 6, 1999, the full disclosure of which is incorporated herein by reference.

### BACKGROUND OF THE INVENTION

1. Field of the Invention

The invention relates to a semiconductor process. More particularly, the invention relates to a method for reducing contact resistance.

2. Description of the Related Art

DRAM application, a polycide is often used to contact an N-type lightly (N−) doped silicon substrate for bitline contacts, as well as to contact an N-type heavily doped (N+) silicon substrate or a polycide gate for local interconnects. Tungsten silicide (WSiₓ) is one of the polycides frequently used in this field. However, a native oxide, which grows instantly subsequent to the formation of the polycide, often leads to a high polycide/polycide contact resistance (Rc). Such native oxide is one of the reasons why local interconnect failure occurs.

As shown in FIG. 1, a wafer that comprises a substrate 100, a gate 108 on the substrate 100, and a dielectric layer 110 covering the substrate 100 and the gate 108 is provided. The wafer further comprises a gate spacer 109 on the sidewall of the gate 108, and a contact hole 112 in the dielectric layer 110. The contact hole 112 exposes the gate 108. The gate 108 comprises a gate polysilicon 104 and a gate WSiₓ 106 on the gate polysilicon 104. The gate WSiₓ 106 often has a native oxide 120 on its surface, because it is exposed to air by the contact hole 112.

In DRAM formation, the dielectric layer 110 is etched to expose the silicon substrate 100 and gate WSiₓ 106 to form contact holes 112 for a cell and periphery. However, the native oxide 120, which is often formed on the gate WSiₓ 106, results in a high contact resistance after subsequent polysilicon 130 deposition.

Two methods may be used to reduce the contact resistance in this field. In a first method, a system with two chambers is used for oxide removal and polysilicon deposition. In the first chamber, HF vapor is used to remove the native oxide 120 on the gate WSiₓ 106 in cluster tools. In the second chamber, a doped-polysilicon layer 130 is then formed on the gate WSiₓ 106 before another WSiₓ layer 132 is deposited. The wafer is conveyed from the first chamber to the second chamber in ambient nitrogen. Without being exposed to air, the undesirable native oxide 120 is not formed on the gate Wsiₓ 106. However, the removing step using the HF vapor often destroys the wafer uniformity. Such issue limits the application of this method.

In addition to the first method, a polycide/polycide contact may be used to obtain a low contact resistance in a second method as shown in FIG. 2. Note that the same reference numbers are used to represent the same elements. In this method, contact holes 112a for a cell and periphery are made separately and are made using two masks (not shown). The first mask is used to etch an oxide layer, thereby accomplishing the formation of contact holes 112a on the substrate. The second mask is used to etch the dielectric layer 110 and the gate WSiₓ 106. The formation of peripheral (not shown) contact holes stops on the doped-polysilicon layer 104. Then, a polycide/polycide contact is accomplished after further doped-polysilicon 130 deposition.

The first method is a feasible method but is not yet mature enough for mass production. The second method is a simple method but is time-consuming due to an additional mask used in the process.

### SUMMARY OF THE INVENTION

The invention provides a method for reducing contact resistance. The method is suitable for use in a wafer that comprises a gate WSiₓ, a native oxide on the gate WSiₓ, and a dielectric layer surrounding and partially covering the gate WSiₓ, wherein the dielectric layer has a contact hole exposing the native oxide. The wafer is placed into a vacuum system. A first polysilicon layer is deposited on the native oxide. The first polysilicon layer and the native oxide are annealed. The depositing step and the annealing step can be continuously repeated in sequence until the native oxide is wholly reacted with the polysilicon layer. A second polysilicon layer is formed on the gate WSiₓ. The wafer is removed from the vacuum system.

Preferably, the first polysilicon layer has a thickness of about 10 angstroms. The vacuum system has a pressure of about 1.0 E-8 torrs. The annealing step is preferably performed without feeding any gas into the ultra-high vacuum (UHV) system, and is preferably performed at a temperature sufficient for the first polysilicon layer to react with the native oxide to produce a gaseous silicon oxide. Consequently, the native oxide is reacted with the first polysilicon layer into a gaseous silicon oxide. More preferably, the annealing step is performed a temperature of about 500° C. to about 800° C.

The proposed method is more economical and faster than the second conventional method mentioned in the background of the invention because the proposed method uses only one mask rather than the two masks used in the second method.

It is to be understood that both the foregoing general description and the following detailed description are exemplary and explanatory only and are not restrictive of the invention, as claimed.

### BRIEF DESCRIPTION OF THE DRAWINGS

FIG. 1 is a schematic, cross-sectional view of a contact hole;

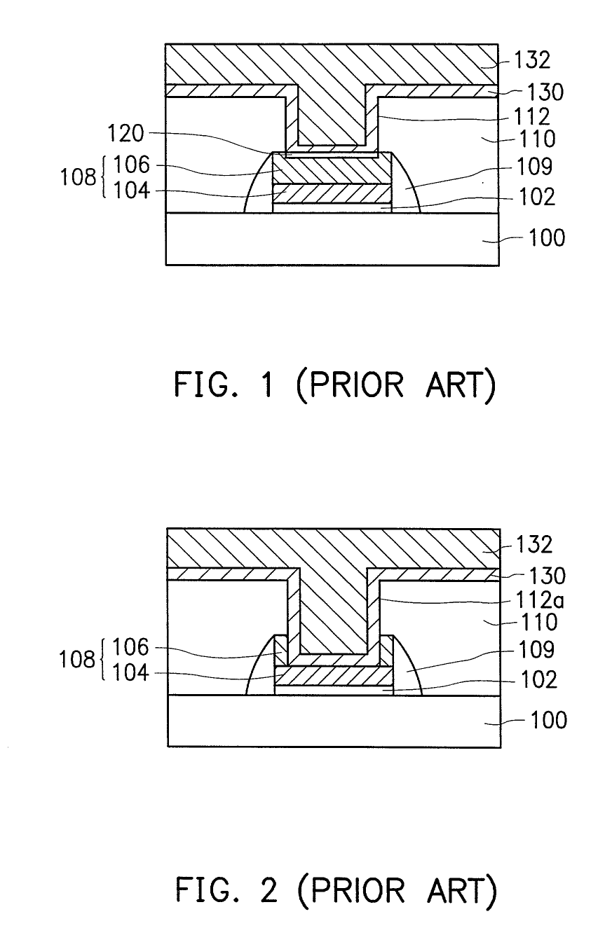

FIG. 2 is another schematic, cross-sectional view of a polycide/polycide contact for resistance reduction;

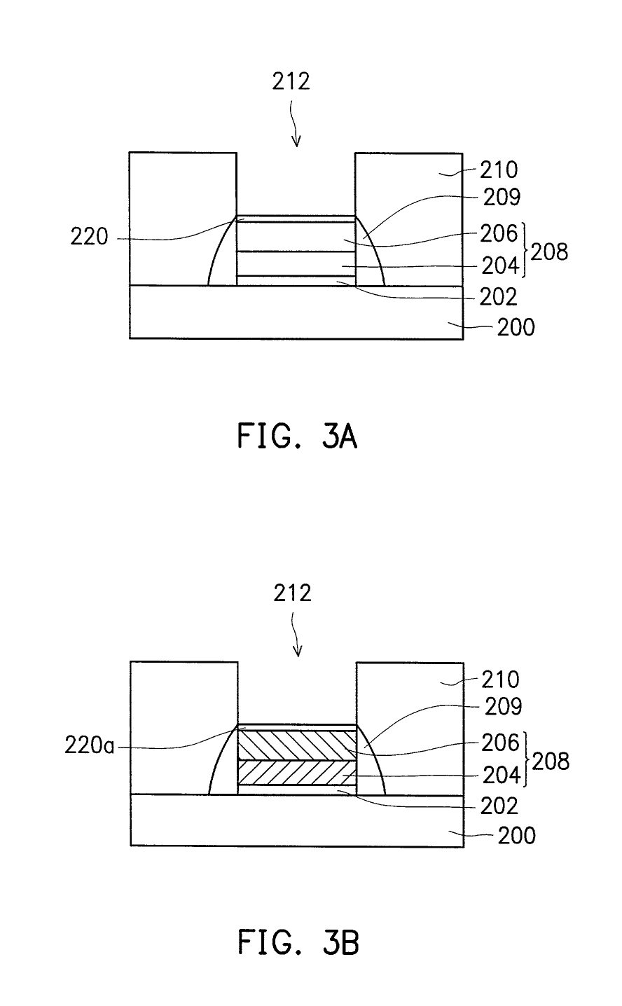

FIGS. 3A-3E are schematic, cross-sectional views of a process for contact resistance (Rc) reduction according to the present invention; and

FIG. 4 is another schematic, cross-sectional view of a wafer comprising a peripheral part.

### DESCRIPTION OF THE PREFERRED EMBODIMENTS

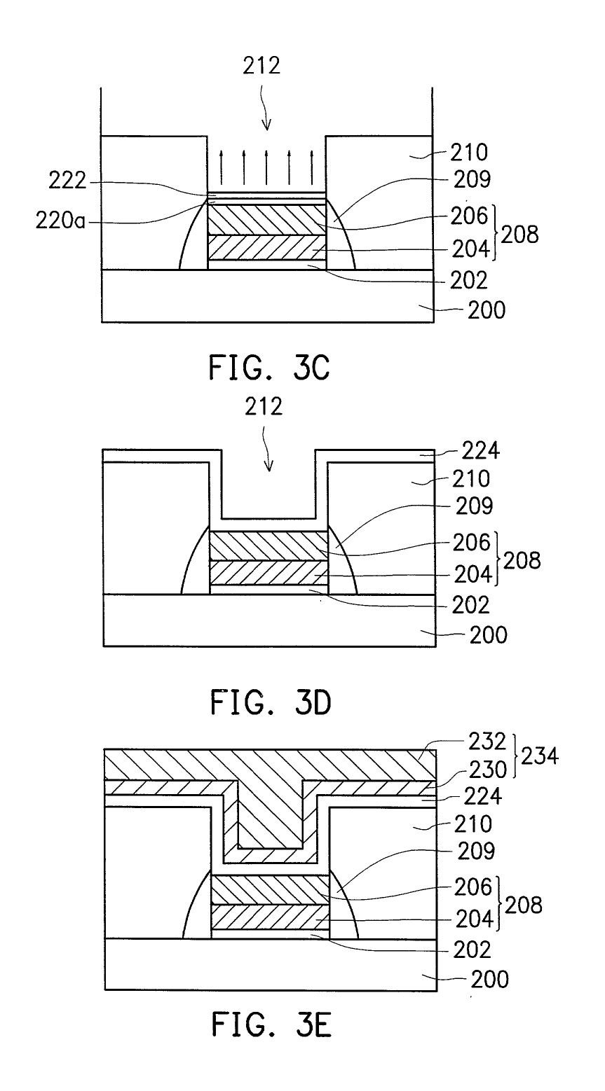

FIGS. 3A-3E are schematic, cross-sectional views of a process for contact resistance (Rc) reduction according to the present invention.

As shown in FIG. 3A, a wafer that comprises a substrate 200, a gate 208 on the substrate 200, and a dielectric layer 210 on the substrate 200 and the gate 208 is provided. The wafer further comprises a gate spacer 209 on the sidewall of the gate 208, and a contact hole 212 in the dielectric layer 210. The contact hole 212 exposes the gate 208. The gate 208 comprises a polysilicon layer 204 and a tungsten silicide (WSiₓ) layer 206 on the polysilicon layer 204. A native oxide 220 is instantly formed subsequent to the formation of the WSiₓ layer 206 because the WSiₓ layer 206 is exposed to air by the contact hole 212. In addition to the structures mentioned above, as shown in the figure, a gate oxide layer 202 is formed on the substrate 200 before the formation of the gate 208.

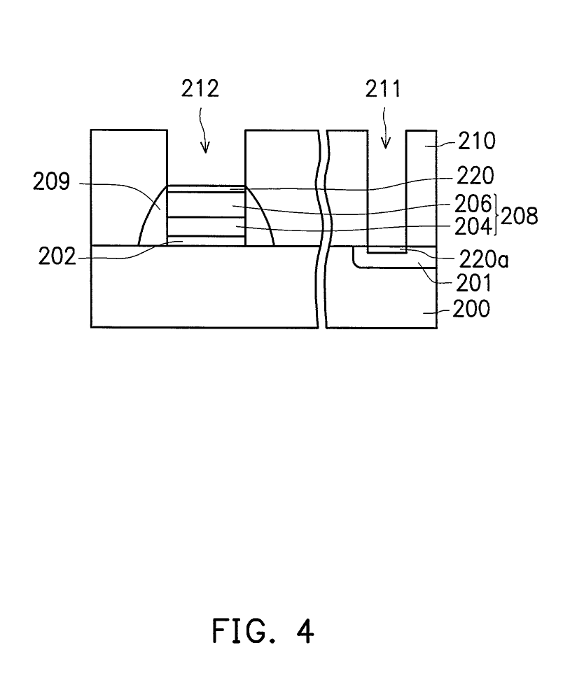

The dielectric layer 210 can further comprise another contact hole 211 in the periphery, as shown in FIG. 4. The periphery of the substrate 200 has a source/drain region 201 under the peripheral contact hole 211. A native oxide layer 220a is also formed on the exposed source/drain region 201. Because of the etching selectively between the dielectric layer 210 and the WSiₓ layer 206, the peripheral contact formation step stops on the WSiₓ layer 206.

As shown in FIG. 3B, the contact hole 212, which exposes the WSiₓ layer 206, is cleaned by a DHF solution to remove a portion of the native oxide (212 shown in FIG. 3A) on the WSiₓ layer 206. After this cleaning step, only a layer of a few molecules of native oxide 220a remains on the WSiₓ layer 206.

The wafer is placed into an ultra high vacuum (UHV) system for further treatment. The pressure of the UHV system can be reduced to about 1.0 E-8 torrs.

As shown in FIG. 3C, a thin polysilicon layer 222 is deposited to about 10 angstroms on the molecular layers of native oxide 220a. The thin polysilicon layer 222 and the molecules of native oxide 220a are then annealed without feeding any gas into the UHV system. Under this annealing treatment, the thin polysilicon layer 222 reacts with the molecules of the native oxide 220a to produce gaseous silicon monoxide at temperatures in the range of about 500-800° C. The depositing step and the annealing step can be continuously repeated in sequence until the the molecular layers of native oxide 220a is wholly reacted with the thin polysilicon layer 222. The reaction for producing the gaseous silicon monoxide is:

Si₍ₛ₎+SiO₂₍ₛ₎→2SiO_{(g)}

Because of the extremely low pressure (about 1.0 E-8 torrs), the resultant silicon monoxide gas (SiO_{(g)}) can be removed from the UHV system even though the reaction of silicon to silicon dioxide (SiO₂) is slow. The thin polysilicon layer 222 and the molecules of native oxide 220a are removed after the annealing treatment.

As shown in FIG. 3D, the WSiₓ layer is in-situ capped with another thin polysilicon layer 224 in the UHV system to avoid oxide re-growth.

It is possible that another native oxide may grow on the surface of the polysilicon layer 224. Therefore, a DHF solution is used to clean the surface of the polysilicon layer 224. After this cleaning step, conventional conductive layers 234, such as doped polysilicon layer 230 and WSiₓ layer 232 are deposited in another piece of equipment to accomplish a contact, as shown in FIG. 3E. The structure shown in FIG. 3E appears to have no contact resistance (Rc). Thus, the proposed method is simple and easy to sustain for future mass production.

Several advantages of the invention are as follows:

1. The proposed method reduces the polycide/polycide contact resistance (Rc).

2. The proposed method is more economical and faster than the second conventional method mentioned in the background of the invention because the proposed method uses only one mask rather than two masks as used in the second method.

3. The proposed method is simple and easy to sustain for future mass production.

Other embodiments of the invention will appear to those skilled in the art from consideration of the specification and practice of the invention disclosed herein. It is intended that the specification and examples to be considered as exemplary only, with a true scope and spirit of the invention being indicated by the following claims.

What is claimed is:

1. A method for reducing contact resistance, the method being suitable for use in a wafer that comprises a gate WSiₓ, a native oxide on the gate WSiₓ, and a dielectric layer surrounding and partially covering the gate WSiₓ, the method comprising:
placing the wafer into a vacuum system;
depositing a first polysilicon layer on the native oxide;
annealing the first polysilicon layer and the native oxide; and
forming a second polysilicon layer on the gate WSiₓ.

2. The method of claim 1, wherein the first polysilicon layer has a thickness of about 10 angstroms.

3. The method of claim 1, wherein the vacuum system has a pressure of about 1.0 E-8 torrs.

4. The method of claim 1, wherein the vacuum system is an ultra high vacuum (UHV) system.

5. The method of claim 4, wherein the annealing step is performed without feeding any gas into the UHV system.

6. The method of claim 1, wherein the annealing step is performed at a temperature of about 500° C. to about 800° C.

7. The method of claim 1, wherein the annealing step is performed at a temperature sufficient for the first polysilicon layer to react with the native oxide to produce a gaseous silicon monoxide.

8. The method of claim 1, further comprising cleaning the native oxide with a first DHF solution before the wafer is placed into the vacuum system.

9. The method of claim 1, further comprising cleaning the second polysilicon layer with a second DHF solution after the second polysilicon layer is formed.

10. A method for reducing contact resistance, the method being suitable for use in a wafer that comprises a gate WSiₓ, a native oxide on the gate WSiₓ, and a dielectric layer comprising a contact hole exposing the native oxide over the substrate, the method comprising:
removing a portion of the native oxide by cleaning the contact hole with a first DHF solution;
placing the wafer into an ultra high vacuum (UHV) system;
depositing a first polysilicon layer on the remaining native oxide;
annealing the first polysilicon layer and remaining native oxide, whereby the first polysilicon layer reacts with the native oxide to produce a gaseous silicon oxide;
capping the gate WSiₓ with a second polysilicon layer;
removing the wafer from the UHV system; and
cleaning the second polysilicon layer with a second DHF solution.

11. The method of claim 10, wherein the first polysilicon layer has a thickness of about 10 angstroms.

12. The method of claim 10, wherein the HUV system has a pressure of about 1.0 E-8 torrs.

13. The method of claim 10, wherein the annealing step is performed at a temperature of about 500° C. to about 800° C.

14. The method of claim 10, wherein the annealing step is performed without feeding any gas into the UHV system.

15. The method of claim 10, wherein the annealing step is performed at a temperature sufficient for the first polysilicon layer to react with the native oxide to produce a gaseous silicon oxide.

16. A method for removing a native oxide, comprising:
cleaning the native oxide with a DHF solution;
placing the native oxide into an ultra high vacuum (UHV) system;
depositing a polysilicon layer on the native oxide; and
annealing the polysilicon layer and the native oxide, whereby the polysilicon layer reacts with the native oxide to produce a gaseous silicon oxide.

17. The method of claim 16, wherein the depositing step and the annealing step are continuously repeated in sequence until the native oxide is wholly reacted with the polysilicon layer.

18. The method of claim 16, wherein the annealing step is performed at a temperature of about 500° C. to about 800° C.

19. The method of claim 16, wherein the annealing step is performed without feeding any gas into the UHV system.

20. The method of claim 16, wherein the annealing step is performed at a temperature sufficient for the polysilicon layer to react with the native oxide to produce a gaseous silicon oxide.
